(19) United States
(12) Patent Application Publication
(10) Pub. No.: US 2010/0045264 A1
(43) Pub. Date: Feb. 25, 2010

(54) PROBE FOR TEMPORARILY ELECTRICALLY CONTACTING A SOLAR CELL

(75) Inventors: Jorg KIESEWETTER, Thiendorf OT Sacka (DE); Axel BECKER, Dresden (DE); Michael TEICH, Moritz OT Friedewald (DE); Claus DIETRICH, Thiendorf OT Sacka (DE); Hartmut WAUER, Dresden (DE)

Correspondence Address: HESLIN ROTHENBERG FARLEY & MESITI PC, 5 COLUMBIA CIRCLE, ALBANY, NY, 12203, US

(73) Assignee: SUSS MicroTec Test Systems GmbH, Sacka (DE)

(21) Appl. No.: 12/539,177

(22) Filed: Aug. 11, 2009

(30) Foreign Application Priority Data
Aug. 19, 2008 (DE) 102008038186.1-35

(51) Int. Cl. G01R 1/06

(52) U.S. Cl. 324/149

(57) ABSTRACT

A probe for temporarily electrically contacting a solar cell for testing purposes, has at least one elastic, electrically conductive contact element for producing the electrical contact, at least one reference sensor for indicating a distance of the contact element to an external reference surface using an electrical signal of the reference sensor, and a mounting plane to which the tip of the contact element is oriented. The probe ensures a secure electrical contact of the solar cell in a testing station with minimal mechanical stress, and is also suitable for use in an industrial continuous production method.

### CROSS REFERENCE TO RELATED APPLICATIONS

This application claims priority of German application no. 10 2008 038 186.1-35 filed on Aug. 19, 2008, the entire disclosure of which is hereby incorporated herein by reference.

### BACKGROUND ART

The invention relates to a probe for temporarily electrically contacting a solar cell for testing purposes.

In the course of the production of solar cells and solar modules comprising solar cells, the electrical contacting of the front and/or rear electric terminals of the solar cell is necessary for their functional testing. Both a reliable electrical contact and also the mechanical sensitivity of the solar cells are to be taken into consideration. On the one hand, the mechanical sensitivity requires a minimization of the force, using which a mechanical and thus electrical contact is produced by probes. On the other hand, a defined force is needed in order to produce the contact securely and ensure it in the course of the measurement. In particular in the event of simultaneous contacting of multiple electric terminals of a solar cell, such high forces occur that they may cause damage to the solar cell because of mechanical loads or strains, in particular if the solar cell is only supported at points by a mount during the testing for minimal shadowing or for the possibility of two-sided contacting.

Thus, for example, in US 2007/0068567 A1, the prior art for the temporary electrical contacting is described, in which a solar cell made of crystalline silicon, whose printed conductors, which are referred to as “fingers,” are contacted directly or via so-called busbars which contact the printed conductors, by multiple probes in the form of contact heads, which each have a diameter of a few millimeters and are pressed individually using springs onto the solar cell. In order to avoid damage due to the contact heads, in US 2007/0068567 A1, probes, which are implemented as flexible, elongate conductors, are pressed onto the contacts of the solar cell on one side or both sides. With this contacting of the solar cell, a relatively high and also locally strongly differentiated force is applied to the solar cell, in order to produce an electrical contact reliably on all fingers and on the entire busbar even in the event of irregularities or if the solar cell is tilted or the probes do not run in parallel.

In addition, the handling of the thin and brittle solar cells, for transfer into a testing station or, in US 2007/0068567 A1, for positioning between two opposing probes and for removal after the testing, causes stress loads which may result in damage to the solar cell. The latter is significant in particular for the production of solar cells in a continuous production facility, because the handling is frequently performed therein using robots, and a correction of imprinted movement sequences in the event of deviations in design and position of the solar cells, for example, is only possible in a limited way for reasons of time and cost.

A further possibility for the temporary contacting of solar cells using probes is described in US patent specification 5,418,680. For the contacting of a plate-shaped solar cell, a probe scans the solar cell using a suitable positioning device. If a strip-shaped configuration of solar cells is contacted, a plurality of probes is situated relative to one another over the continuously movable strip in such a manner that scanning occurs through the strip transport. The described problems also cannot be remedied using this device.

### BRIEF SUMMARY OF THE INVENTION

The invention is thus based on the object of disclosing a probe, using which a solar cell can be contacted in a testing station with minimal mechanical stress and while ensuring a secure electrical contact, the probe also being suitable for use in an industrial continuous production method.

The stated object is achieved by a probe, whose feed movement to the solar cell is controllable on the basis of a distance measurement from the probe to a reference surface, which is not part of the probe and is to be referred to hereafter as the external reference surface. As a result thereof, the force introduced into a solar cell by the probe may be metered precisely and adapted to the particular conditions. This reference surface will typically be a surface of the solar cell to be contacted, alternatively, other reference surfaces, which have a geometric relationship to the solar cell, are also usable, however. The control is implemented with the aid of a reference sensor of the probe, in that known geometrical relationships between the reference sensor and the one or also multiple contact elements of the probe may be related to the solar cell with the aid of the distance measurement by the reference sensor. The control of the feed movement of the probe is made possible by an electrical signal, i.e., a reference signal which is generated by the reference sensor.

A known geometrical relationship between the reference sensor and a contact element is producible both by situating the two in direct proximity and also having a lateral and/or vertical offset to one another. In that the reference sensor is a component of the probe, it is moved jointly therewith in any case, so that the geometry does not change. A geometrical reference of the probe to the contacting device and especially to its positioning and movement system is regularly produced by the mounting of the probe, so that one or more contact elements and, thereof, in particular the tips are oriented to a mounting plane. Using a plane as the reference allows multiple contact elements to be oriented to this plane, e.g., so that the tips of the contact elements lie in a plane which is parallel to the mounting plane.

A feed movement is to be understood here as the movement of the probe which is executed by the probe after production of a relative position between probe and solar cell in a direction up to the final production of the contact. It thus comprises the feed movement until reaching the reference position signaled by the reference sensor, the following continuation of this movement in the same direction until the touching of an electrode terminal by a contact element, and, in addition, the continuation of this feed movement, generally referred to as overtravel, for producing a secure contact which is independent of mechanical or thermal strains, for example. The yielding embodiment of the contact element ensures the overtravel, which is precisely executable because of the control possible using the reference sensor.

The overtravel is a variable which is primarily a function of the materials used in the components to be brought into contact with one another, the size of the terminal surfaces, the machine technology executing the movement, and the tolerances of these parameters. It is typically experimentally ascertained, in order to ensure that the probe is not plastically deformed during the overtravel, that a surface to be contacted is not penetrated or otherwise damaged by the probe, and the probe does not leave this surface, e.g., by displacement of the components to one another. The feed movement can be controlled until the production of a secure contact using the knowledge of the overtravel from an experimental series on the particular contacting device used.

The execution of the overtravel allows a so-called “scrub” to be executed using the feed movement. To this end, the contact tips scrape over the electrode terminal because of their displacement during the overtravel and thus remove possible contaminants or passivation layers. In this way, it is possible to increase the contact reliability solely by the execution of the feed movement. A design of the contact elements as bending springs already in particular allows a scrub. If the bending springs are situated at an acute angle to the contact plane, even a slight overtravel results in sufficient scrub. In addition, the load introduced into the solar cell is minimized by the displacement of the contact elements on the electrode terminal of a solar cell in the event of such a configuration of the bending springs.

If an elastically deformable, electrically conductive plastic body is used as the contact element instead of the bending springs in a design of the probe, a scrub is also executable by a structuring of the surface of the plastic body and a lateral movement of the probe.

Although only one probe has been described up to this point and is described hereafter, this also applies to a plurality thereof, because a precise geometrical association between each contact element, reference planes of the probe, and the reference sensor is also always possible in these cases because of the known configuration of the contact elements to one another. In this manner, it is possible to contact various electrode terminals. Thus, the placement on a single contact island is possible, as is the simultaneous contacting of a complex terminal structure or a busbar of monocrystalline or polycrystalline solar cells. Their so-called fingers, which run in parallel, are also contactable using the described probe.

Various components, which have an influence on the location of the reference sensor relative to the contact element and thus on the distance measurement, are usable as the reference sensor. If a scanning sensor is used, its scanning tip lies in a plane with the tips of the one or more contact elements, referred to hereafter as the contact plane, so that the contact element of the probe already rests on the electrode terminal when the reference signal is generated, and the following final feed movement is solely used for the overtravel. In sensors which measure a distance, such as optical sensors, the final feed movement is composed as described above.

Alternatively, multiple reference sensors may also be used for the distance measurement and thus for the control of the feed movement. For example, in two-dimensionally extended probes having linearly or flatly distributed contact elements, tilting of the probe during the feed movement may be prevented by suitable numbers and positions of reference sensors, in that the reference signals generated using the individual reference sensors are used for the local differentiated movement of the probe. This is supported if a suitable mount of a probe allows the tilting thereof via one or two axes. For this purpose, a probe, which extends along an extension direction or in a plane, has a mount having two or more joints, so that the system is statically determined, i.e., the number of the reactions in these bearings is equal to the number of the degrees of freedom of the probe. This prevents tensions from occurring in the probe or in the solar cells during the contact, which may cause damage to one or both thereof.

In one design, a probe has a three-fingered structure, the fingers lying so closely to one another that they may be laid adjacent to one another even on an electrode terminal surface of less than 1 mm. The middle finger of such a structure represents the contact element, while the two outer fingers are reference elements which have a defined reference potential, which does not impair the measurement, such as ground potential, applied to them to generate the reference signal. All three fingers are spring-elastic and are mounted like booms on a bracket in such a manner that their tips experience a deflection during the brief continuation of the feed movement after their contact on the electrode terminal, i.e., the overtravel, which has a directional component in the feed movement and a directional component perpendicular thereto. In this way, the “scrub” described above is possible using the feed movement, because the directional component of the deflection of the tip of the contact element which runs perpendicular to the feed movement causes the scraping of the tips over the electrode terminal.

Because of a time delay, which typically occurs upon placement of the reference elements or a scanning sensor, between the contact element and the actual end of the feed movement, sufficient overtravel already frequently occurs because of this delay due to the measuring technology.

In a comparable way, a series of contact elements may be situated adjacent to one another, which are connected in parallel for the joint placement on a high-resistance electrode terminal, such as a printed busbar. With such a linear or flat extension of the probe, in order to prevent the tilting thereof to the electrode terminal surface and thus corruption of the testing, as described above, two or more reference sensors may be situated on the probe, which may signal a uniform spacing of various points of the probe to the external reference surface and thus to the solar cell. The greatest possible spacing between the reference sensors would achieve the best leveling of the probe in this case. The reference sensors may be two fingers, which have a reference potential applied to them to generate a contact signal as the reference signal, or other suitable scanning or spacing sensors.

### BRIEF DESCRIPTION OF THE DRAWING FIGURES

The invention is explained in greater detail hereafter on the basis of exemplary embodiments. In the associated drawing:

FIGS. 1A, 1B show designs of probes for the electrical function testing of solar cells having a plurality of contact elements,

FIG. 2 shows a top view of a probe according to FIG. 1B,

FIG. 3 shows a design of a probe having a plurality of bending springs,

FIGS. 4A, 4B show two designs of probes having a plurality of bending springs and an at least sectionally trapezoidal probe cross-section,

FIGS. 5, 6, 7 show various circuit configurations of the contact elements and reference sensors of probes.

### DETAILED DESCRIPTION

Various designs of solar cells may be electrically contacted for testing purposes in various manufacturing steps using the probes described hereafter, in that the configuration of the contact elements 31 is adaptable to the location and the size of the electrode terminals 2 of the solar cells 1. To test a solar cell 1, it is temporarily, i.e., only over a defined time interval of the testing, and removably contacted by probes and subjected to a light flash directed toward the front side and incident almost entirely thereon. A current generated by the light action and a voltage are tapped as the measuring signal via the probes 30 and supplied to analysis. The contacting is performed only by laying the probes 30 on the electrode terminals 2 of the solar cell 1, and the contact is interrupted by lifting the probes 30. In this way, a series of solar cells 1 can be temporarily contacted, tested, and transported further continuously.

The probe described hereafter is to be usable for contacting a polycrystalline solar cell, which has a plurality of fingers, which collect current and which are connected to one another by two busbars, on its front side, which faces upward. The designs of the probes allow both the individual fingers to be contacted as the electrode terminals, in that a shared contact element 31 is laid over all fingers or in that a separate contact element 31 is placed on each finger. The contacting of the individual fingers of a monocrystalline or polycrystalline solar cell is possible as a result of the very precise and thus close configuration of the individual contact elements and, in addition, by a positioning precision of the probe of up to 50 μm. This high resolution also allows contact islands which are situated in a raster having a raster spacing to one another in such magnitudes, for example, to be contactable individually by individual contact elements.

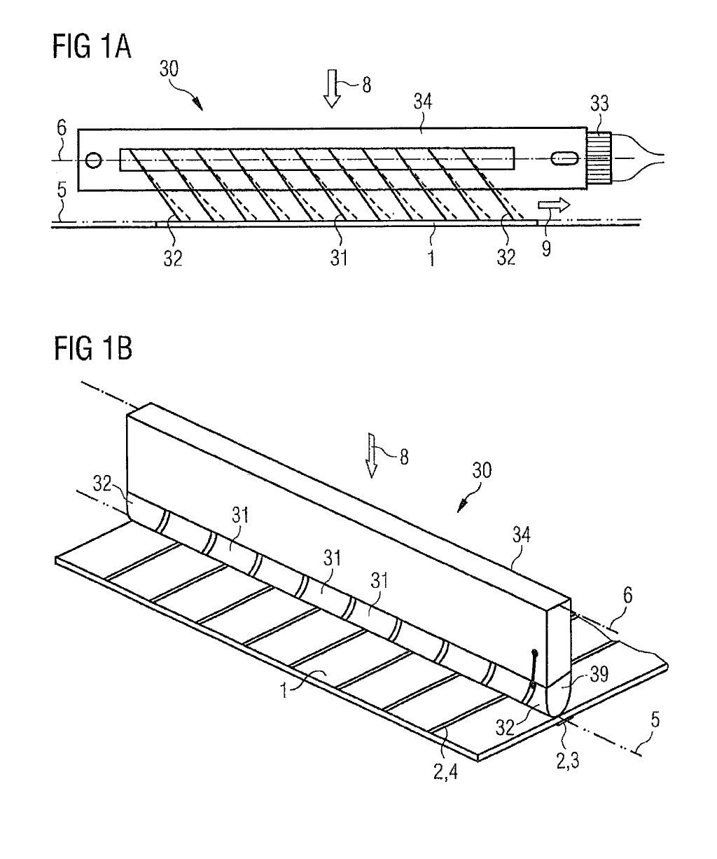

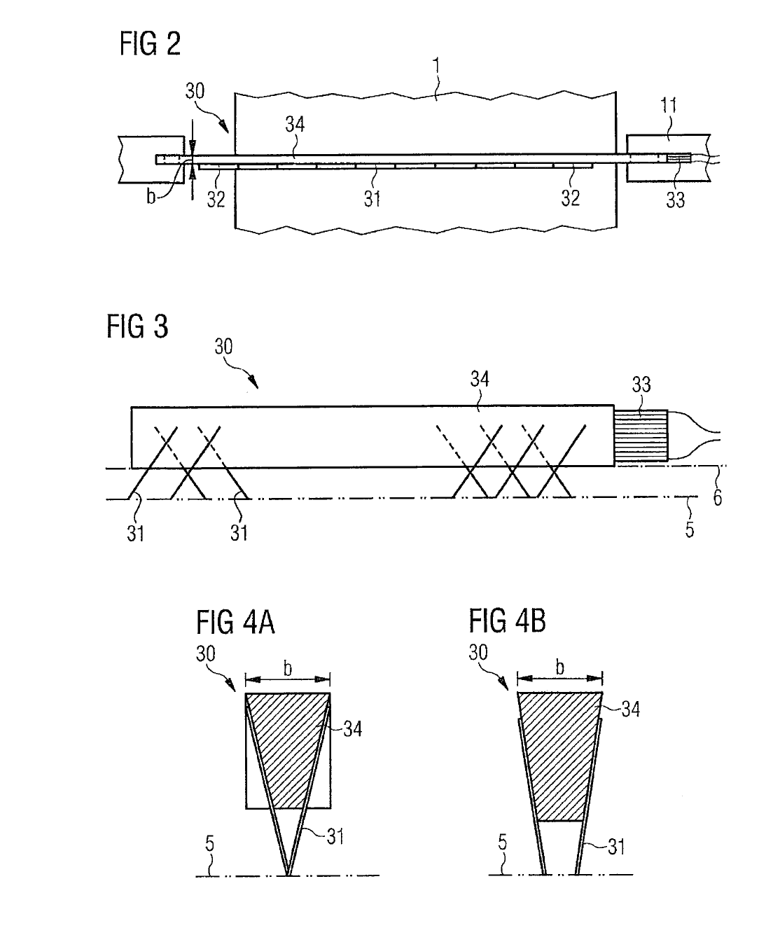

The probes 30 according to FIGS. 1A and 1B each comprise a bar 34, which has a rectangular shape in cross-section, whose narrower sides are parallel to the contact plane 5. Because of this on-edge configuration, the probe 30 has a higher stability for the feed movement 8 perpendicular to the contact plane 5. In addition, this cross-section ensures a narrow base in the top view, so that upon an exposure of the solar cell 1 in the direction of the feed movement, no or only minimal shadowing of the optically active area of the solar cell occurs (FIG. 2). Both probes of FIGS. 1A and 1B have a plurality of contact elements 31, whose lower terminals, to be laid on the electrode terminals 2 of a solar cell 1, which are referred to hereafter as tips, independently of the actual shape, lie in a plane, the contact plane 5.

The contact elements 31, which are implemented as bending springs, in FIG. 1A are situated adjacent to one another like a comb on the bar 34 in such a manner that they project beyond the lower edge of the bar 34 and enclose an acute angle with the contact plane 5. The contact plane 5 regularly corresponds to the surface of the solar cell 1 in which the electrode terminals 2 to be contacted (not shown) lie. The angled configuration of the contact elements 31 of the probe allows the deformation thereof (shown by dashed lines) if this feed movement is briefly continued after the vertical placement, shown by the arrow of the feed movement 8, on the electrode terminal 2. As described in detail above, it is ensured in this manner that all contact elements 31 are seated on the electrode terminal 2.

Simultaneously, the contact elements 31 experience, after their placement as a result of the angled configuration and as a result of the feed movement 8 executed perpendicular to the surface of the solar cell 1, a deflection 9, which runs nearly parallel to the surface of the solar cell 1, upon continuation of the feed movement 8. As a result of this deflection 9, the tips of the contact elements 31 scratch a short distance over the electrode terminal 2, whereby the uppermost layer thereof, typically a passivation layer, is scraped off and a good electrical contact is produced, described in detail above as a “scrub.”

The two outer bending springs in FIG. 1A are the reference elements 32 of a reference sensor. They are placed simultaneously with the contact elements 31 on the busbar, which extends under all bending springs, and thus generate the reference signal via the high-resistance connection of the busbar, which indicates that the reference sensor is at the distance of zero to the reference surface, i.e., the busbar. The overtravel triggered by the reference signal deflects all bending springs uniformly and, as described above, produces a reliable contact between the contact elements 31 and the busbar.

Alternatively, instead of the reference elements 32, separate reference sensors 31 may also be situated on the ends of the probes 30 or at another point of the probes 30. These deliver separate reference signals to indicate the distance of the particular end of the probe 30 to an external reference surface (not shown).

The bar 34 of the probe 30 has two holes in one plane, the mounting plane 6, which are used for mounting the probe 30 in a contacting device. The mounting plane 6 defined by the holes, which are to be produced very precisely, a round hole and an oblong hole, especially the center points thereof, is capable of integrating the geometrically-defined relationship of the tips of the contact elements 31 to the mounting plane in a contacting device, so that a defined geometrical relationship to the movement and positioning units thereof is producible via this plane, which is the basis of the feed movement of the probe 30 to the solar cell 1. Depending on the mounting of the various possible designs of the probes 34, various planes may be used as mounting planes, if they may be used as a reference plane for both the probe and also the contacting device.

The probe according to FIG. 1B is mounted having its upper terminal surface on a surface of the contacting device, for example, so that this upper terminal surface functions as the mounting plane 6. The contact plane represents the lower terminus of the contact element 31, which is implemented as a sealing lip.

This probe 30 is a further possible design for the elongate contacting of a busbar 3 or a series of fingers 4, which are situated in parallel, of a solar cell 1, for example. The contact elements 31 and also the two reference elements 32, which are situated on the edge of the probe, are implemented here by an elastically deformable lip 39 made of plastic, whose surface is sectionally electrically conductive through coating. Each section represents one element 31, 32. By situating the reference elements 32 on both ends of the probe 30, a contacting of only one side of this elongate probe 30 as a result of the tilting thereof over the longitudinal extension may be avoided, because the contact signal is only generated if both ends are seated on the busbar 3. Through suitable flexible mounting of the probe 30 or alternatively through two separate drives (not shown), one for each end of the probe 30, a one-sided mechanical load of the solar cell 1 by tilting of the probe 30 may be avoided.

Alternatively to the conductive surface, the plastic itself can also be conductive, for example, through electrically conductive particles. In this case, the division of the lip 39 into individual elements 31, 32 may be implemented by repeated interruption of the lip 39 itself or the electrical conductivity thereof. The contacting with the electrode terminal 2 of the solar cell 1 is performed by pressing on the lip 39 flatly over its entire length. Reference is made to the description of FIG. 1A in regard to the design and configuration of the reference sensor(s).

The probe 30 according to FIG. 1A is shown in horizontal projection in FIG. 2. It is obvious here that the probe 30 is very narrow in the exposure direction, which is coincident with the flash direction, in order to minimize the shadowing. In addition, the special mounts 11 are pressed far enough outward that they do not throw shadows on the solar cell. The electrical terminal 33 of the probe 30, a plug connector here, is also situated laterally to the solar cell.

In another design (FIG. 3), the contact elements 31 are distributed uniformly on both sides of the bar 34 and situated in the opposing direction, in order to compensate for a torque acting on the bar 34 as a result of the deflection 9 of the contact elements 31. Further configurations for compensating for a torque or a tension introduced in the solar cell 1 by the overtravel are possible. Thus, the contact elements 31 may be situated on one side of the bar 34, but nonetheless situated angled in both directions. This is possible, for example, either using contact elements 31 running toward the center of the bar or directed away from the center. In this way, the apparent crossing of contact elements which can be seen in the side view can be prevented. In addition, one-sided processing of the probe simplifies the production thereof.

FIGS. 4A and 4B show further possible configurations of the contact elements 31 on a bar 34 having equilateral trapezoidal cross-section. The trapezoidal cross-section allows a very close-lying double-row or also single-row configuration of the tips of the contact elements 31. The contact elements 31 may either be fastened on the lateral face of the trapezoid by soldering, gluing, or clamping or other suitable mounting means (FIG. 4) or countersunk in slots which are introduced into the bar 34 and define the location of the contact elements 31. The bar 34 only has the trapezoidal cross-section in the area of the slots.

The electrical connection of the contact elements 31 and reference elements 32 in FIGS. 1A and 1B (not shown) occurs via contact conductors and reference conductors along or in the interior of the bar 34. The contact elements 31 and possibly also the reference elements 32 are electrically and mechanically connected to the printed conductors by solder joints, but may also be connected in another way, e.g., by clamping or plugging. Further possible electrical connections of contact elements 31 and one or two reference sensors 32 or the particular reference elements 32 of these reference sensors 32 are shown in FIGS. 5 through 7.

FIG. 5 schematically shows a circuit diagram of the two contact conductors 35 (force and sense) for the electrical connection of the contact elements 31 and the two reference conductors for the electrical connection of the two reference elements 32, situated on each end of the probe 30, to a measuring instrument (not shown) or a control unit.

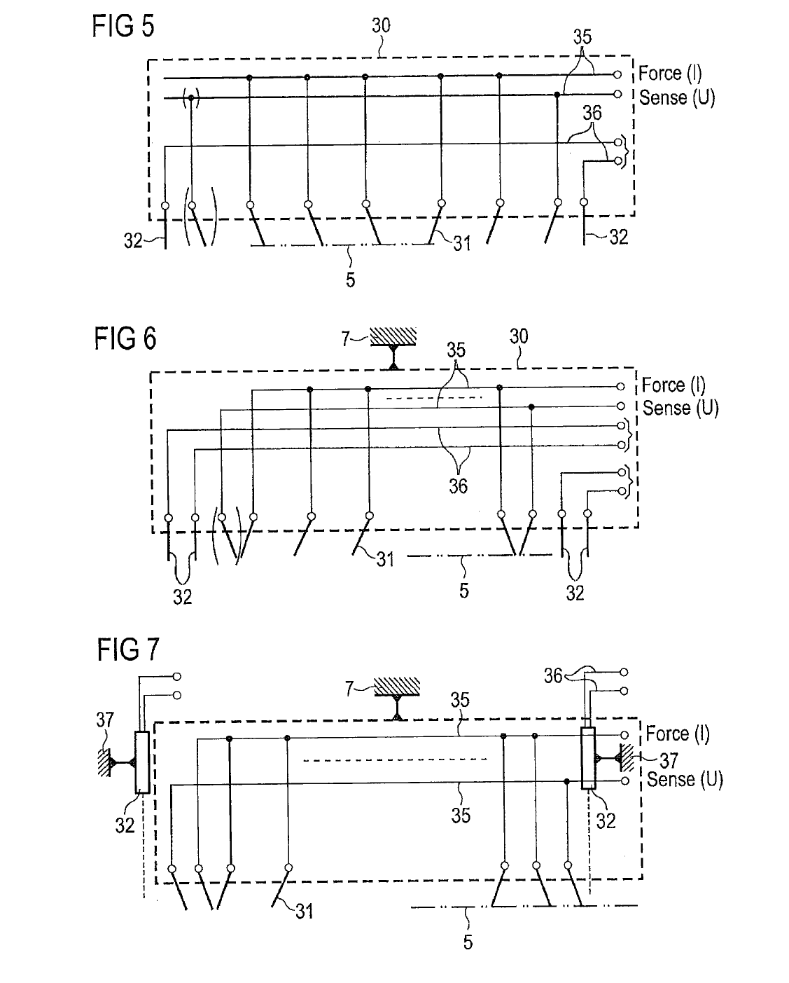

The probe 30 in FIG. 6 has one reference sensor on each end, formed from two reference elements 32 in each case, whose tips are situated in a plane, the contact plane 5, with the tips of the contact elements 31. Because of this leveling of the probe 30 using two reference sensors, the probe comprises a pivotable mount 7 for the mounting of the probe 30 in a contacting device (not shown). The electrical connection of the contact elements 31 and the reference elements 32 is performed as described for FIG. 5.

According to FIG. 7, the probe 30 has two optical reference sensors 32, which indicate a spacing to the contact plane 5, instead of the reference sensors formed from reference elements 32. To produce the geometric relationship, described in detail above, between the reference sensors 32 and the contact elements 31, the reference sensors 32 have a geometrical relationship 37 (schematically shown) in FIG. 7. Reference is made again to the above statements in regard to the electrical connections.

We claim:

1. A probe for temporarily electrically contacting a solar cell for testing purposes, comprising
at least one elastic, electrically conductive contact element for producing electrical contact with the solar cell,
at least one reference sensor for indicating a distance of the at least one contact element to an external reference surface using an electrical signal of the at least one reference sensor, and
a mounting plane to which a tip of the at least one contact element is oriented.

2. The probe according to claim 1, wherein the at least one contact element comprises a plurality of contact elements situated adjacent to one another in such a manner that tips of the contact elements lie in a contact plane, the contact elements being connected in parallel and the at least one reference sensor being situated, for indicating an inclination of the contact plane to a surface of the solar cell.

3. The probe according to claim 2, wherein the at least one reference sensor comprises two reference sensors situated at a distance to one another to indicate an inclination of the contact plane to the surface of the solar cell.

4. The probe according to claim 1, wherein the probe further comprises a mount for pivotable connection of the probe.

5. The probe according to claim 4, wherein the mount has bearings in a type and number such that the probe is connectable in a statically determined manner to a contacting device, so that number of reactions of the probe in the bearings is equal to number of degrees of freedom of the probe.

6. The probe according to claim 1, wherein the at least one contact element comprises an electrically conductive bending spring situated at an acute angle to the contact plane.

7. The probe according to claim 6, wherein the at least one contact element comprises multiple similar contact elements, and some of the contact elements are situated in an orientation opposite to remaining contact elements in relation to a virtual straight line perpendicular to the contact plane.

8. The probe according to claim 2, wherein the at least one contact element comprises two contact elements situated on two diametrically opposing lateral surfaces of a bar.

9. The probe according to claim 8, wherein the bar at least sectionally has a trapezoidal cross-section.

10. The probe according to claim 1, wherein the at least one contact element comprises an elastically deformable, electrically conductive plastic body.

11. The probe according to claim 1, wherein the at least one reference sensor comprises two elastic, electrically conductor reference elements electrically insulated from the at least one contact element and situated adjacent to the at least one contact element in such a manner that reference and contact elements can be placed adjacent to one another on an electrode terminal of the solar cell.
